(19) United States
(12) Patent Application Publication
(10) Pub. No.: US 2024/0105810 A1
(43) Pub. Date: Mar. 28, 2024

(54) VERTICAL FERRORELECTRIC FIELD-EFFECT TRANSISTOR (FEFET) DEVICES

(71) Applicant: Intel Corporation, Santa Clara, CA (US)

(72) Inventors: Rachel A. Steinhardt, Beaverton, OR (US); Ian Alexander Young, Olympia, WA (US); Dmitri Evgenievich Nikonov, Beaverton, OR (US); Marko Radosavljevic, Portland, OR (US); Matthew V. Metz, Portland, OR (US); John J. Plombon, Portland, OR (US); Raseong Kim, Portland, OR (US); Kevin P. O'Brien, Portland, OR (US); Scott B. Clendenning, Portland, OR (US); Tristan A. Tronic, Aloha, OR (US); Dominique A. Adams, Portland, OR (US); Carly Rogan, North Plains, OR (US); Arnab Sen Gupta, Hillsboro, OR (US); Brandon Holybee, Portland, OR (US); Punyashloka Debashis, Hillsboro, OR (US); I-Cheng Tung, Hillsboro, OR (US); Gauri Auluck, Hillsboro, OR (US)

(73) Assignee: Intel Corporation, Santa Clara, CA (US)

(21) Appl. No.: 17/952,161

(22) Filed: Sep. 23, 2022

(51) Int. Cl. H01L 29/51; H01L 29/66; H01L 29/78

(52) U.S. Cl. CPC H01L 29/516; H01L 29/6684; H01L 29/66969; H01L 29/7831

(57) ABSTRACT

In one embodiment, transistor device includes a first source or drain material on a substrate, a semiconductor material on the first source or drain material, a second source or drain material on the semiconductor material, a dielectric layer on the substrate and adjacent the first source or drain material, a ferroelectric (FE) material on the dielectric layer and adjacent the semiconductor material, and a gate material on or adjacent to the FE material. The FE material may be a perovskite material and may have a lattice parameter that is less than a lattice parameter of the semiconductor material.

### BACKGROUND

In current ferroelectric field-effect transistor (FeFET) devices, the ferroelectric (FE) material layers (e.g., perovskite materials, such as BaTiO₃ or BaFeO₃) may be epitaxially deposited on a semiconductor template material with a larger lattice constant. The tensile strain caused by this can force the polarization of the FE material to be in-plane, i.e., in the same direction as the channel between the source/drain regions of the device, which is not ideal for FeFET devices.

### BRIEF DESCRIPTION OF THE DRAWINGS

FIG. 1 illustrates an example conventional FeFET device.

FIG. 2 illustrates an example vertical FeFET device in accordance with embodiments herein.

FIG. 3 illustrates an example dual gate vertical FeFET device in accordance with embodiments herein.

FIGS. 4A-4B illustrate example stacked vertical FeFET devices in accordance with embodiments herein.

FIGS. 5A-5B illustrate example stacked, dual-gate vertical FeFET devices in accordance with embodiments herein.

FIG. 6 illustrates an example process of manufacturing a vertical FeFET in accordance with embodiments herein.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIG. 9 is a cross-sectional side view of an integrated circuit device assembly that may include a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

Embodiments herein describe vertical FeFET devices in which the source/drain regions of the device are above and below a semiconductor channel layer (in a vertical stack), with a ferroelectric (FE) material layer adjacent to the semiconductor channel layer. For example, in certain embodiments, perovskite FE materials such as BaTiO₃ and BiFeO₃ may be epitaxially deposited together with an oxide semiconductor layer, such as (La—Ba)SnO₃, which has a larger lattice constant/lattice parameter than the perovskite FE materials. As used herein, (A-B) (e.g., La—Ba) may refer to elements A and B in proportions AₓB₍₁₋ₓ₎ (e.g., LaₓBa₍₁₋ₓ₎SnO₃). The relative difference in the lattice constant/lattice parameters of the materials along with their positioning allows the polarization of the perovskite FE material to be perpendicular to the channel between the source/drain regions in which current flows, which can lead to more ideal FeFET device properties. For example, some embodiments may allow for decreased operating voltage of FeFET devices, increased density of transistors on an integrated circuit device, three-dimensional scalability, or ferroelectric non-volatile memory applications.

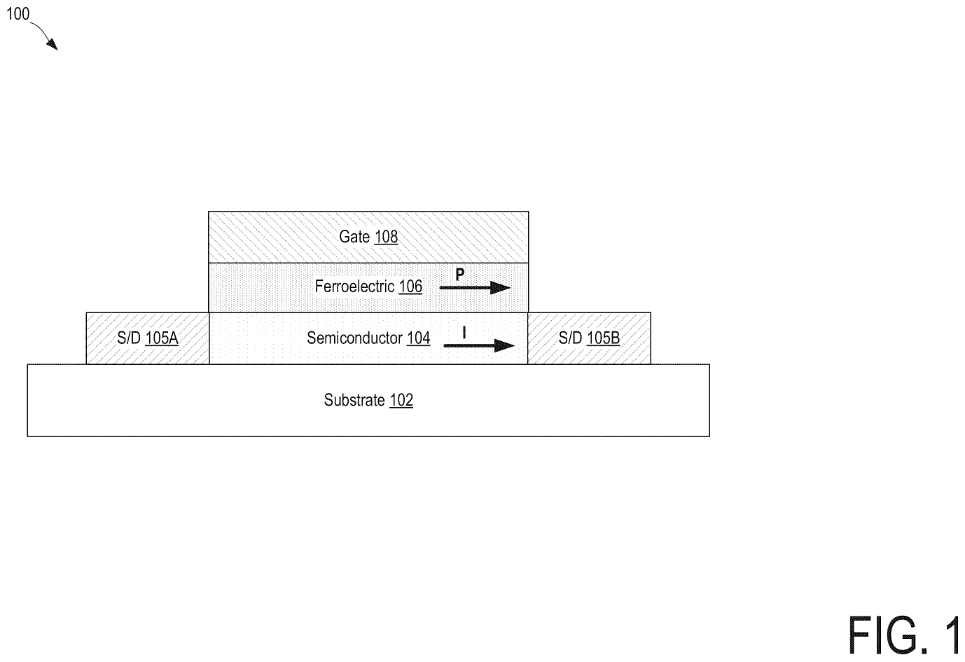

FIG. 1 illustrates an example conventional FeFET device 100. The example device 100 includes a substrate 102 with an oxide semiconductor material 104 formed on the substrate 102 and source/drain regions 105 adjacent the oxide semiconductor material 104 on either side. The device 100 also includes an FE material 106 on the oxide semiconductor material 104, and a gate contact 108 on the FE material 106. As used herein, a “source/drain region” or “source/drain material” may refer to a region or material that may be implemented either as a source or drain of a transistor device, depending on the implementation of the device (e.g., voltages applied to the respective source/drain regions or source/drain materials). For example, in some implementations, the source/drain region 105A may be implemented as a source of the device 100 and the source/drain region 105B may be implemented as a drain of the device 100, while in other implementations, the source/drain region 105A may be implemented as a drain of the device 100 and the source/drain region 105B may be implemented as a source of the device 100.

FeFET devices may be used to store information based on the polarization of the FE material 106, and the polarization of the FE material 106 may be based on application of a voltage to the gate contact 108. In current FeFET designs, e.g., those using non-perovskite FE materials and Group III-V semiconductor materials, the polarization of the FE material 106 is in the vertical direction with respect to FIG. 1, i.e., pointing either toward or away from the semiconductor material 104 and generally perpendicular to the direction of current in the channel within the semiconductor material 104.

Certain materials, such as (La—Ba)SnO₃, have emerged as a promising candidate for oxide semiconductor channels in FeFET devices (e.g., semiconductor material 104 of the device 100) because of its high mobility and oxygen stability. FeFET devices using (La—Ba)SnO₃ and a perovskite FE material may lead to decreased operating voltages due to the small coercivity of perovskite ferroelectrics. However, (La—Ba)SnO₃ has the highest mobility when it is grown epitaxially on a lattice-matched substrate and the lattice parameter of (La—Ba)SnO₃ (4.116 A) is significantly larger than that of FE perovskites (e.g., in-plane lattice parameter of BaTiO₃ is 3.99 A, and the lattice parameter of BiFeO₃ is 3.96 A). When these perovskite FE materials are grown with such a large tensile strain, the polarization of the FE material points in-plane (e.g., as shown in FIG. 1, generally in parallel with the direction of current in the semiconductor channel). This can limit the application to deplete channel of a (La—Ba)SnO₃ semiconductor material directly below it, which in turn limits three-dimensional (3D) scaling if FET architectures, such as the one shown in FIG. 1, are used.

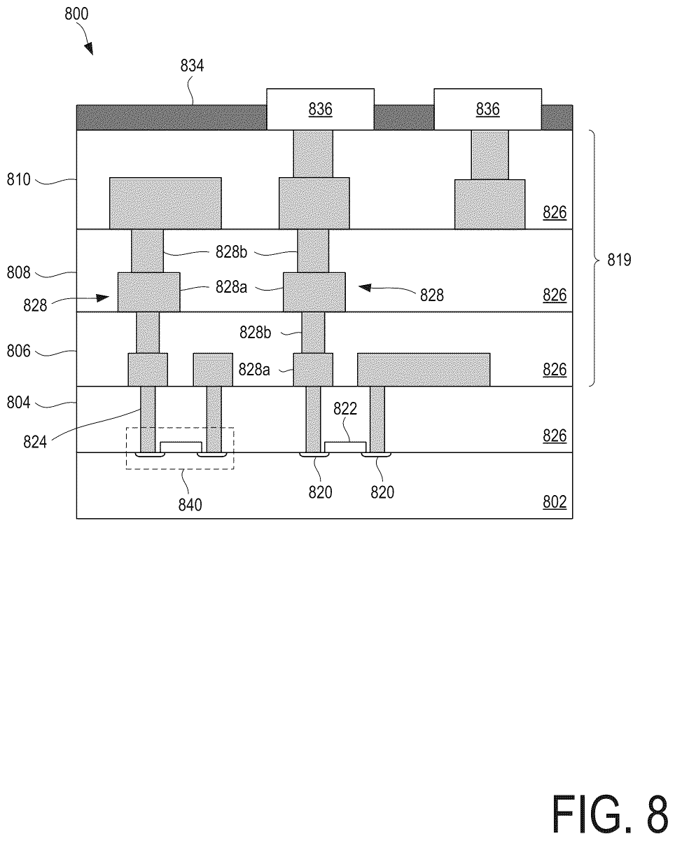

A vertical FeFET structure as described herein may overcome these or other issues, and could allow the in-plane polarization to be utilized to deplete a channel as well as allow 3D stacking of the device(s). This could also benefit the electrical properties of the (La—Ba)SnO₃ channel material as it could allow it to be grown in a superlattice structure with the source/drain regions having similar lattice constants/lattice parameter, such as metallic higher doped (La—Ba)SnO₃, which can lead to fewer defects in the channel and therefore higher mobility. The example vertical FeFET devices described herein may be used as a transistor in an integrated circuit device (e.g., as a transistor 840 in the integrated circuit device 800 of FIG. 8).

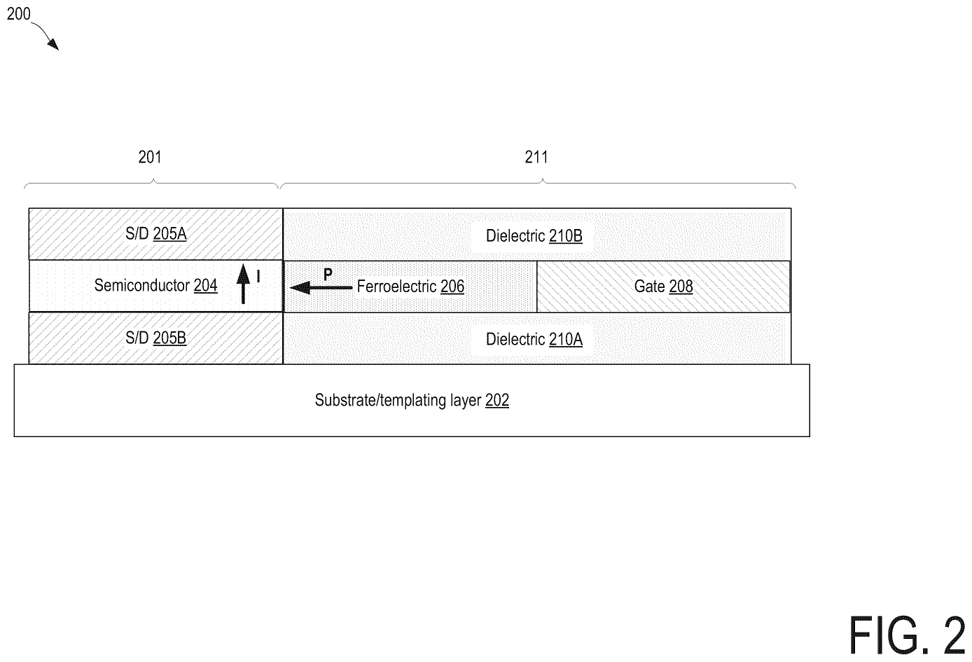

FIG. 2 illustrates an example vertical FeFET device 200 in accordance with embodiments herein. The example device 200 includes a substrate/templating layer 202 (hereinafter referred to as just a substrate) with a channel stack 201 formed thereon. The channel stack 201 includes a first source/drain region 205B formed on the substrate 202, a semiconductor layer 204 formed on the source/drain region 205B, and a second source/drain region 205A formed on the semiconductor layer 204. The device 200 also includes a gate stack 211 formed on the substrate 202, which includes a first dielectric layer 210A formed on the substrate 202 adjacent to the source/drain region 205B, a FE material 206 formed on the dielectric layer 210A and adjacent the semiconductor material 204, a gate contact 208 formed on the dielectric layer 210A and adjacent the FE material 206, and a second dielectric layer 210B formed on the FE material 206 and the gate contact 208. In certain embodiments the channel stack 201 may be grown first, and the gate stack 211 grown thereafter. In other embodiments, the gate stack 211 may be grown first, and the channel stack 201 grown thereafter.

The FE material 206 may be a perovskite material, and the semiconductor material 204 may be selected such that the lattice parameter of the semiconductor material 204 is larger than the lattice parameter of the FE material 206. The perovskite FE material 206 may accordingly grow with a large tensile strain that causes the polarization of the FE material 206 to point in-plane as shown in FIG. 2, which causes the direction to be generally perpendicular with the direction of current in the semiconductor channel as shown. Example semiconductor materials for use in the semiconductor layer 204 include a doped BaSnO₃ (e.g., doped with La or other dopants such as neodymium (Nd)), doped SrTiO₃ (e.g., doped with La or other dopants such as Nd), IGZO (Indium Gallium Zinc Oxide), LaNiO₃, SrSnO₃, or (Ba—Sr)SnO₃, and example perovskite FE materials for use in FE material layer 206 include BaTiO₃, Ba(Zr—Ti)O₃, (Ba—Ca)TiO₃, (Ba—Sr)TiO₃, (Ba—Ca)(Ti—Zr)O₃, BiFeO₃, (Bi—La)FeO₃, Bi(Fe—Co)O₃, LiNbO₃, or KNbO₃.

The substrate 202 may include a template material (e.g., an oxide template material), which may be lattice-matched to one or more of the materials grown thereon. The substrate 202 may be formed, for example, from SrTiO₃, GdScO₃, DyScO₃, LaAlO₃, BaHfO₃, BaZrO₃, SrZrO₃, SrHfO₃, LaInO₃, LaScO₃, LaLuO₃, La(LuSc)O₃, or MgO. In some embodiments, the substrate 202 may be a templating material layer that is formed on a conventional Silicon-based (e.g., SiO₂) or similar type of substrate material (not shown).

The source/drain regions 205 and/or gate contact 208 may include SrRuO₃, (Sr—Ba)RuO₃, (La—Ba)SnO₃, (La—Sr)MnO₃, (La—Ba)CoO₃, LaNiO₃, LaRuO₃, YBa₂Cu₃O₇, SrVO₃, SrCoO₃, SrMoO₃, Pt, Ru, Ir, Pd, W, Mo, RuO₂, IrOx, or MoO₂. It will be understood that the device 200 may also include a metal or conductive oxide that is connected to the source/drain regions 205 to form source/drain contacts. The dielectric materials 210 may be formed, for example, from one of SiO₂, HfO₂, SrTiO₃, LaAlO₃, BaHfO₃, BaZrO₃, SrZrO₃, SrHfO₃, LaInO₃, LaScO₃, LaLuO₃, La(LuSc)O₃, MgO, or Al₂O₃.

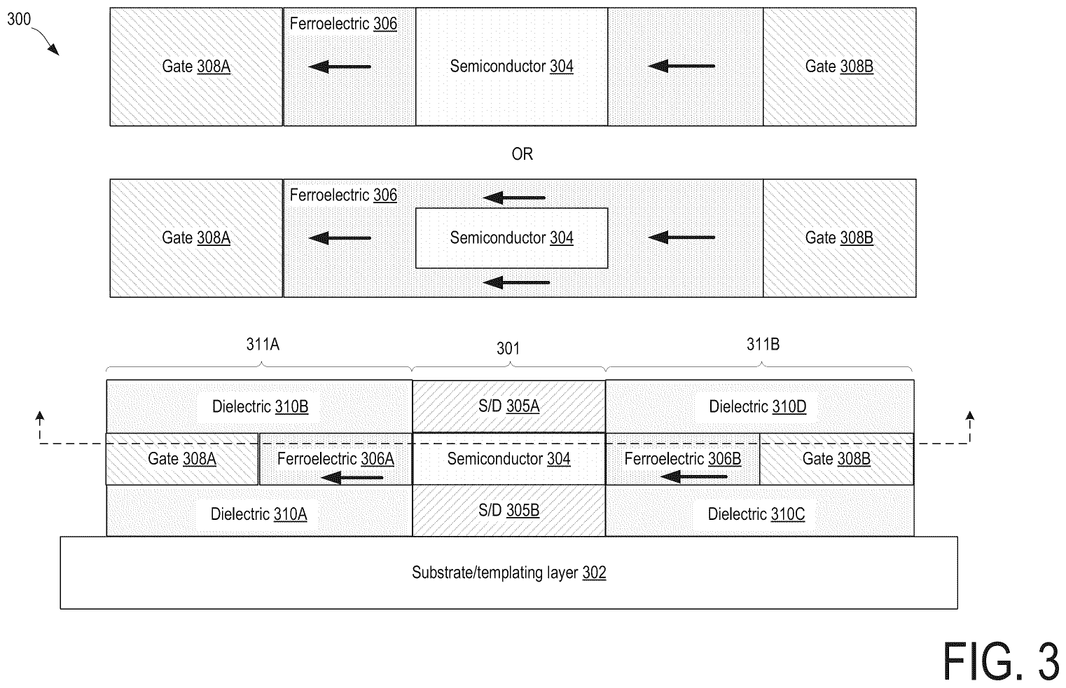

FIG. 3 illustrates an example dual gate vertical FeFET device 300 in accordance with embodiments herein. The configuration of the example device 300 is similar to the device 200 of FIG. 2, but with gate stacks 311A, 311B on each side of the channel stack 301. The channel stack 301 is the same as the channel stack 201 and includes a first source/drain region 305B formed on the substrate 302, a semiconductor layer 304 formed on the source/drain region 305B, and a second source/drain region 305A formed on the semiconductor layer 304. Likewise, each gate stack 311A/311B includes a first dielectric layer 310A/310C formed on the substrate 302 and adjacent to the source/drain region 305B, a FE material 306A/B formed on the dielectric layer 310A/310C and adjacent the semiconductor material 304, a gate contact 308A/308B formed on the dielectric layer 310A/310C and adjacent the FE material 306, and a second dielectric layer 310B/310D formed on the FE material 306A/306B and the gate contact 308A/308B.

The top of FIG. 3 illustrates top views of different example configurations for the side view shown in the bottom of FIG. 3. In the top configuration shown, the width of the semiconductor material 304 spans the entirety of the FE material 306, while in the bottom configuration shown, the semiconductor material 304 is surrounded by the FE material 306 on all sides. In certain embodiments, the source/drain regions 305 may have a similar configuration to the FE material 306 as that of the semiconductor material 304. For instance, in the bottom configuration shown, both the semiconductor material 304 and the source/drain regions 305 above and below the semiconductor material 304 may be surrounded by the FE material 306.

Like the example shown in FIG. 2, in certain embodiments, the channel stack 301 may be formed first before the gate stacks 311 are formed on either side, while in other embodiments, the gate stacks 311 may be formed first before the channel stack 301. The gate stacks 311A, 311B may be formed at the same time as each other. The materials used for the source/drain regions 305 and the semiconductor layer 304 may be the same as those described above with respect to the same components (e.g., the FE materials 306 may use the same example materials described above with respect to the FE material 206 and the semiconductor material 304 may use the same example materials described above with respect to the semiconductor material 204).

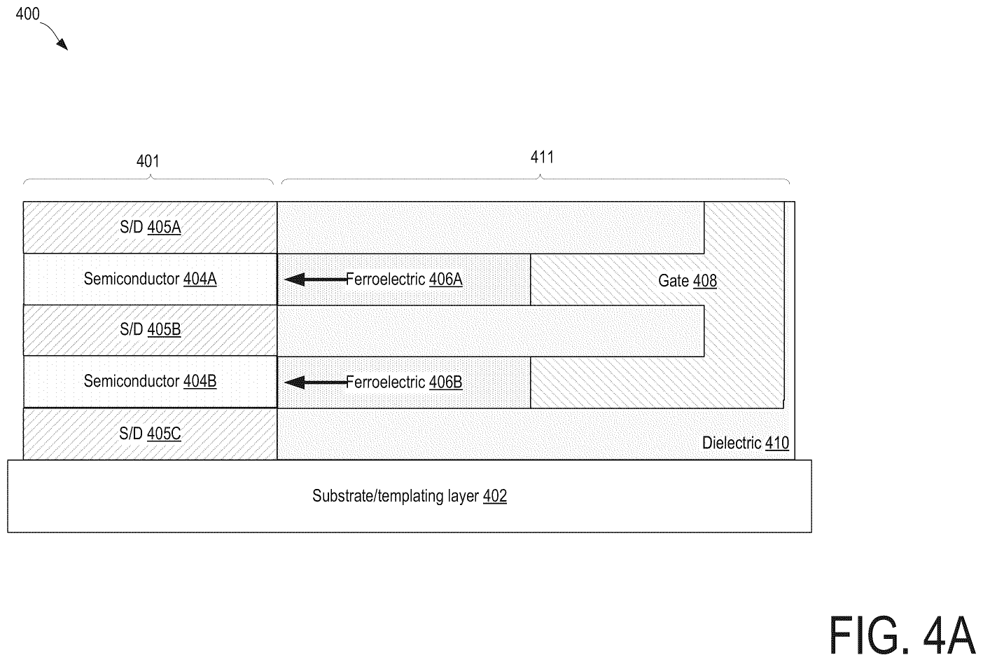

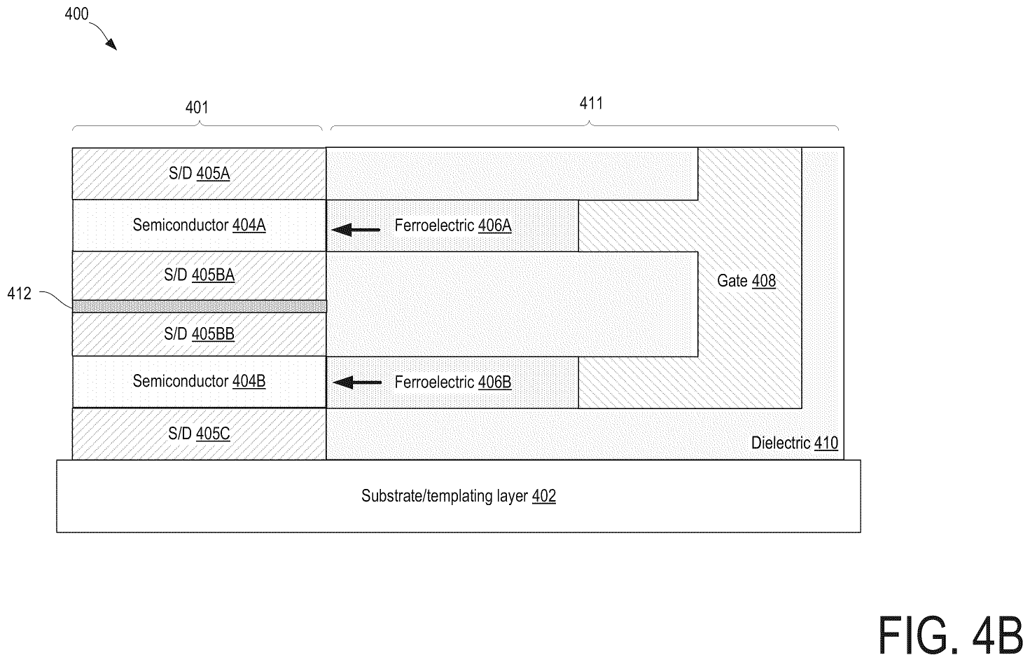

FIG. 4A illustrates an example stacked vertical FeFET device 400 in accordance with embodiments herein. The example device 400 is similar to the device 200 but has an additional semiconductor material layer and source/drain region within its channel stack 401, and a corresponding additional FE material and gate contact portion in the gate stack 411. Although one additional stack layer is shown in each of the channel stack 401 and gate stack 411 (i.e., one additional semiconductor layer and source/drain layer for the channel stack 401, and one additional FE material in the gate stack adjacent the additional semiconductor layer and source/drain layer), other embodiments may include additional stack layers. For example, a device may include two, three, four, five, or more additional stack layers, repeating the same pattern as shown in FIG. 4A.

The channel stack 401 includes a first source/drain region 405C formed on the substrate 402, a first semiconductor layer 404B formed on the source/drain region 405C, a second source/drain region 405B formed on the first semiconductor layer 404B, a second semiconductor layer 404A formed on the source/drain region 405B, and a third source/drain region 405A formed on the second semiconductor layer 404A. The gate stack 411 includes a respective FE material layer 406A/406B adjacent each semiconductor layer 404A/404B, and a gate contact 408 that is in contact with each of the FE material layers 406A, 406B with a dielectric 410 surrounding and isolating the FE material layers.

As in the previous examples, in certain embodiments, the channel stack 401 may be formed first before the gate stack 411 is formed, while in other embodiments, the gate stack 411 may be formed first before the channel stack 401. The materials used for each of the various layers/portions of the device 400 may be the same as those described above with respect to the same components (e.g., the FE materials 406 may use the same example materials described above with respect to the FE material 206 and the semiconductor materials 404 may use the same example materials described above with respect to the semiconductor material 204).

FIG. 4B illustrates the example stacked vertical FeFET device 400 of FIG. 4A, but with a dielectric layer 412 between two middle source/drain regions 405BA and 405BB.

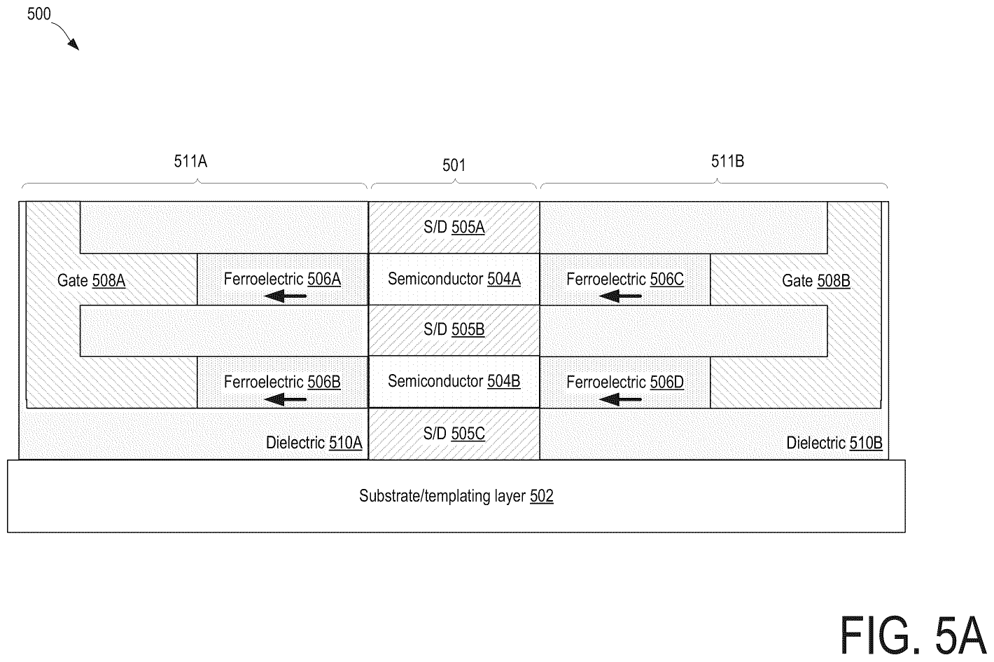

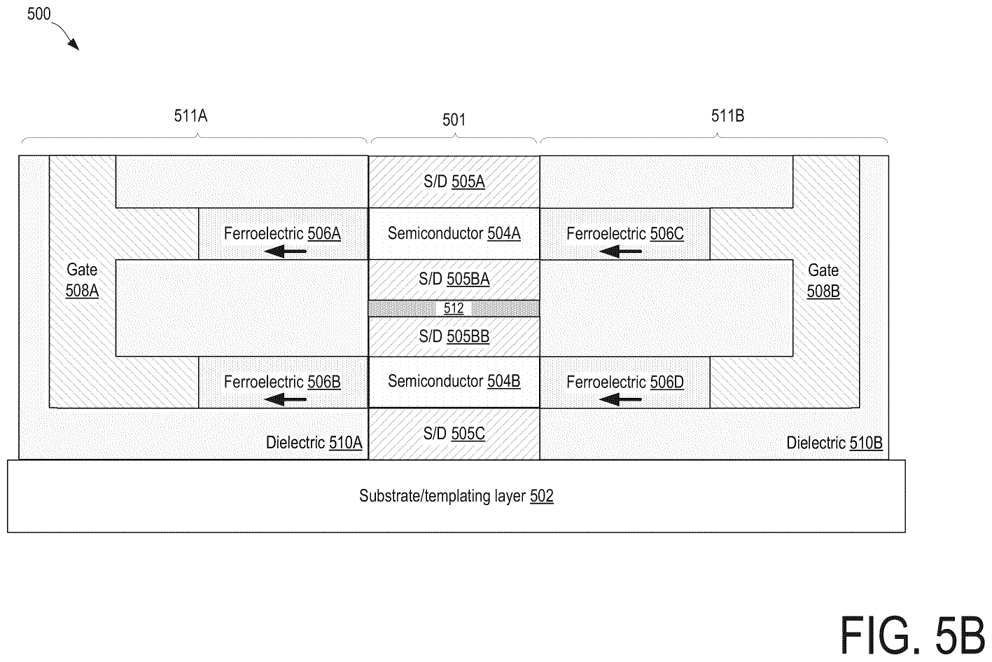

FIG. 5A illustrates an example stacked, dual-gate vertical FeFET device 500 in accordance with embodiments herein. The configuration of the example device 500 is similar to the device 400 of FIGS. 4A-4B, but with gate stacks 511A, 511B on each side of the channel stack 501. The channel stack 501 is the same as the channel stack 401 and includes a first source/drain region 505C formed on the substrate 502, a first semiconductor layer 504B formed on the source/drain region 505C, a second source/drain region 505B formed on the first semiconductor layer 504B, a second semiconductor layer 504A formed on the source/drain region 505B, and a third source/drain region 505A formed on the second semiconductor layer 504A. The gate stacks 511A/511B include a respective FE material layer adjacent each semiconductor layer (506A and 506C adjacent 504A, and 506B and 506D adjacent 504B), and a gate contact 508A/508B that is in contact with each of the FE material layers in the respective gate stack. Each gate stack 511A/511B also includes a dielectric 510A/510B surrounding and isolating the FE material layers in the respective gate stack.

Like the example shown in FIGS. 4A-4B, in certain embodiments, the channel stack 501 may be formed first before the gate stacks 511 are formed on either side, while in other embodiments, the gate stacks 511 may be formed first before the channel stack 501. The gate stacks 511A, 511B may be formed at the same time as each other. The materials used for the source/drain regions 505 and the semiconductor layer 504 may be the same as those described above with respect to the same components (e.g., the FE materials 506 may use the same example materials described above with respect to the FE material 406 and the semiconductor material 504 may use the same example materials described above with respect to the semiconductor material 404).

FIG. 5B illustrates the example FeFET device 500 of FIG. 5A, but with a dielectric layer 512 between two middle source/drain regions 405BA and 405BB.

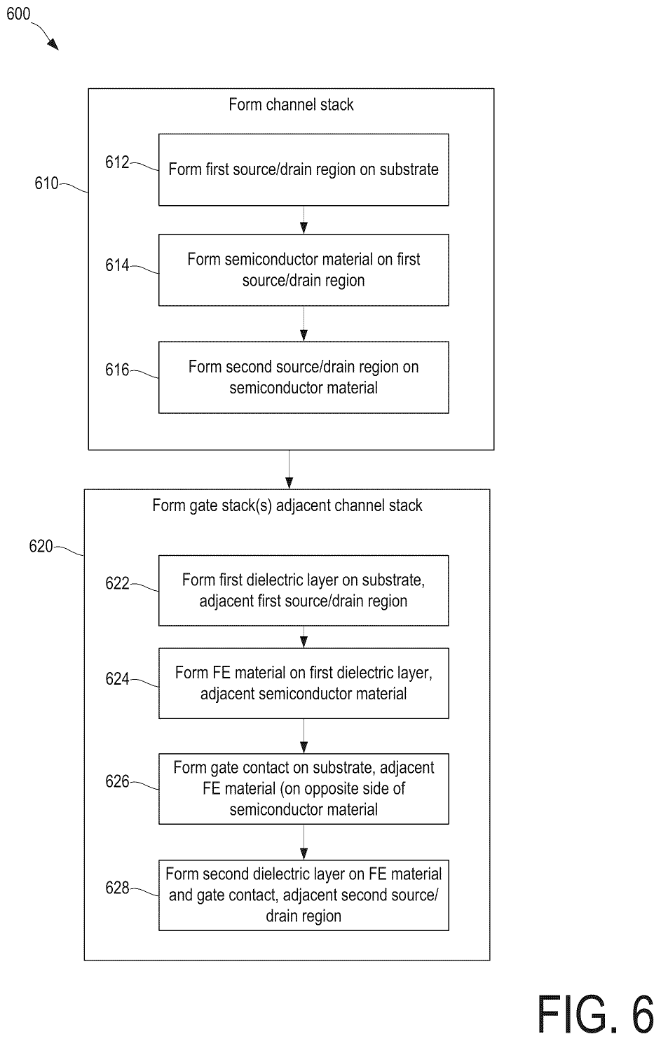

FIG. 6 illustrates an example process 600 of manufacturing a vertical FeFET in accordance with embodiments herein. The example process shown may include additional, fewer, or different operations than those shown or described below. In some embodiments, one or more of the operations shown in FIG. 6 include multiple operations, sub-operations, etc.

At 610, a channel stack (e.g., 201, 301, 401, 501) of the vertical FeFET is formed. This may include forming, at 612, a first source/drain region (e.g., 205B, 305B, 405C, 505C) on a substrate (e.g., 202, 302, 402, 502), forming, at 614, a semiconductor material layer (e.g., 204, 304, 404B, 504B) on the first source/drain region, and forming, at 616, a second source/drain region (e.g., 205A, 305A, 405B, 505B) on the semiconductor material. In certain embodiments, additional layers may be formed within the channel stack, e.g., forming an additional semiconductor material layer (e.g., 404A, 504A) on the second source/drain region, and forming an additional source/drain region (e.g., 405A, 505A) on the second semiconductor material layer, and so on for as many layers as designed. Each of the respective materials may be chosen from the examples of each type of material described above.

At 620, one or more gate stacks (e.g., 211, 311A. 311B, 411, 511A, 511B) of the vertical FeFET are formed adjacent the channel stack formed at 610. This may include forming, at 622, a first dielectric layer (e.g., 210A, 310A, 310C) on the substrate, forming, at 624, an FE material (e.g., 206, 306A, 306B, 406B, 506B, 506D) on the first dielectric layer and adjacent the semiconductor material, forming, at 626, a gate contact (e.g., 208, 308A, 308B) on the first dielectric layer and adjacent the FE material (e.g., on an opposite side of the FE material from the semiconductor material), and forming, at 628, a second dielectric layer (e.g., 210B, 310B, 310D) on the FE material and gate contact and adjacent the second source/drain region. In certain embodiments, additional layers may be formed within each gate stack, e.g., forming an additional FE material layer (e.g., 406A, 506A) and gate contact on the second dielectric layer, and forming an additional dielectric layer above the additional FE material and gate contact, and so on for as many layers as designed. Each of the respective materials may be chosen from the examples of each type of material described above. In embodiments where multiple gate stacks are implemented, each gate stack may be formed simultaneously, e.g., each respective layer of the gate stack is formed at the same time, or each gate stack may be formed at different times.

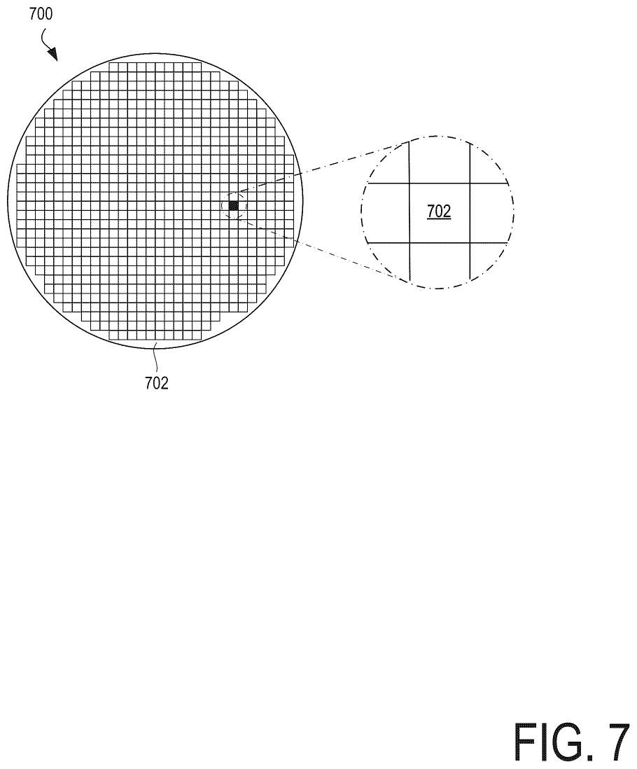

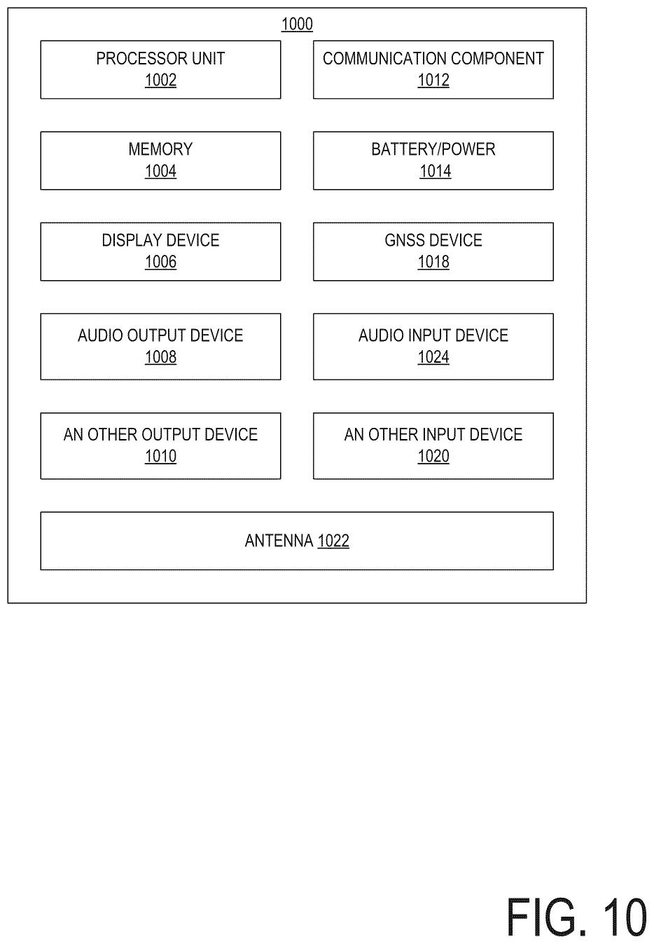

FIG. 7 is a top view of a wafer 700 and dies 702 that may incorporate any of the embodiments disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may include one or more transistors (e.g., some of the transistors 840 of FIG. 8, discussed below), supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1002 of FIG. 10) or other logic that is configured to store information in the memory devices or execute instructions stored in the memory array.

FIG. 8 is a cross-sectional side view of an integrated circuit device 800 that may be included in any of the embodiments disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs) or ferroelectric field-effect transistors (FeFETs), e.g., those described herein) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 8, the example transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material. However, in other embodiments, the transistors 840 may be FeFETs that are formed as described in detail above.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page from the perspective of FIG. 8. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the die 800, and the metallization stack 819 can be used to route I/O signals from the conductive contacts 836 to transistors 840 and any other components integrated into the die 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

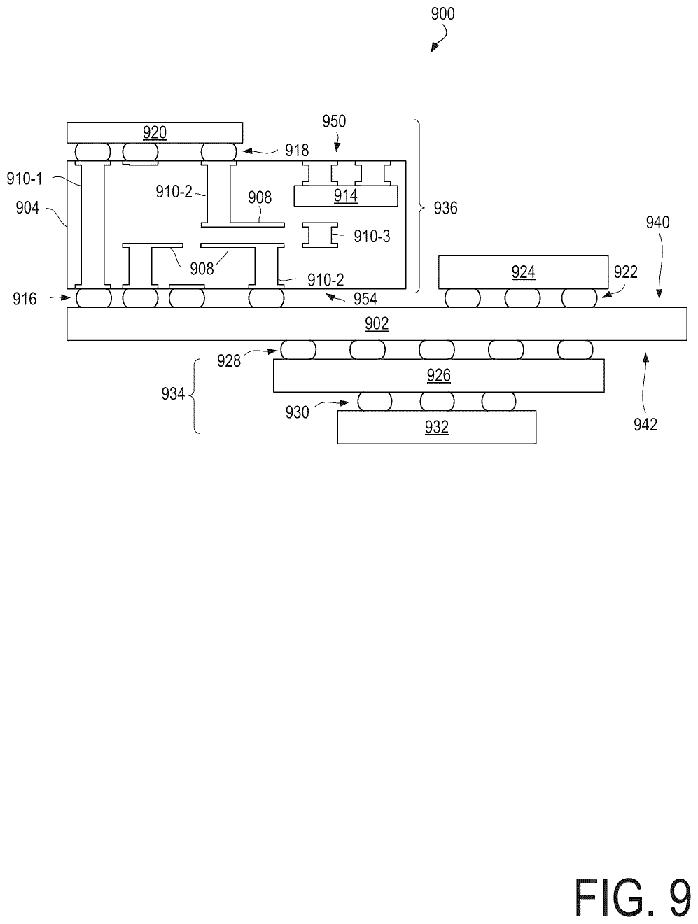

FIG. 9 is a cross-sectional side view of an integrated circuit device assembly 900 that may include any of the embodiments disclosed herein. The integrated circuit device assembly 900 includes a number of components disposed on a circuit board 902 (which may be a motherboard, system board, mainboard, etc.). The integrated circuit device assembly 900 includes components disposed on a first face 940 of the circuit board 902 and an opposing second face 942 of the circuit board 902; generally, components may be disposed on one or both faces 940 and 942.

In some embodiments, the circuit board 902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 902. In other embodiments, the circuit board 902 may be a non-PCB substrate. The integrated circuit device assembly 900 illustrated in FIG. 9 includes a package-on-interposer structure 936 coupled to the first face 940 of the circuit board 902 by coupling components 916. The coupling components 916 may electrically and mechanically couple the package-on-interposer structure 936 to the circuit board 902, and may include solder balls (as shown in FIG. 9), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 936 may include an integrated circuit component 920 coupled to an interposer 904 by coupling components 918. The coupling components 918 may take any suitable form for the application, such as the forms discussed above with reference to the coupling components 916. Although a single integrated circuit component 920 is shown in FIG. 9, multiple integrated circuit components may be coupled to the interposer 904; indeed, additional interposers may be coupled to the interposer 904. The interposer 904 may provide an intervening substrate used to bridge the circuit board 902 and the integrated circuit component 920.

The integrated circuit component 920 may be a packaged or unpacked integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 920, a single monolithic integrated circuit die comprises solder bumps attached to contacts on the die. The solder bumps allow the die to be directly attached to the interposer 904. The integrated circuit component 920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 904 may spread connections to a wider pitch or reroute a connection to a different connection. For example, the interposer 904 may couple the integrated circuit component 920 to a set of ball grid array (BGA) conductive contacts of the coupling components 916 for coupling to the circuit board 902. In the embodiment illustrated in FIG. 9, the integrated circuit component 920 and the circuit board 902 are attached to opposing sides of the interposer 904; in other embodiments, the integrated circuit component 920 and the circuit board 902 may be attached to a same side of the interposer 904. In some embodiments, three or more components may be interconnected by way of the interposer 904.

In some embodiments, the interposer 904 may be formed as a PCB, including multiple metal layers separated from one another by layers of dielectric material and interconnected by electrically conductive vias. In some embodiments, the interposer 904 may be formed of an epoxy resin, a fiberglass-reinforced epoxy resin, an epoxy resin with inorganic fillers, a ceramic material, or a polymer material such as polyimide. In some embodiments, the interposer 904 may be formed of alternate rigid or flexible materials that may include the same materials described above for use in a semiconductor substrate, such as silicon, germanium, and other group III-V and group IV materials. The interposer 904 may include metal interconnects 908 and vias 910, including but not limited to through hole vias 910-1 (that extend from a first face 950 of the interposer 904 to a second face 954 of the interposer 904), blind vias 910-2 (that extend from the first or second faces 950 or 954 of the interposer 904 to an internal metal layer), and buried vias 910-3 (that connect internal metal layers).

In some embodiments, the interposer 904 can comprise a silicon interposer. Through silicon vias (TSV) extending through the silicon interposer can connect connections on a first face of a silicon interposer to an opposing second face of the silicon interposer. In some embodiments, an interposer 904 comprising a silicon interposer can further comprise one or more routing layers to route connections on a first face of the interposer 904 to an opposing second face of the interposer 904.

The interposer 904 may further include embedded devices 914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 904. The package-on-interposer structure 936 may take the form of any of the package-on-interposer structures known in the art. In embodiments where the interposer is a non-printed circuit board

The integrated circuit device assembly 900 may include an integrated circuit component 924 coupled to the first face 940 of the circuit board 902 by coupling components 922. The coupling components 922 may take the form of any of the embodiments discussed above with reference to the coupling components 916, and the integrated circuit component 924 may take the form of any of the embodiments discussed above with reference to the integrated circuit component 920.

The integrated circuit device assembly 900 illustrated in FIG. 9 includes a package-on-package structure 934 coupled to the second face 942 of the circuit board 902 by coupling components 928. The package-on-package structure 934 may include an integrated circuit component 926 and an integrated circuit component 932 coupled together by coupling components 930 such that the integrated circuit component 926 is disposed between the circuit board 902 and the integrated circuit component 932. The coupling components 928 and 930 may take the form of any of the embodiments of the coupling components 916 discussed above, and the integrated circuit components 926 and 932 may take the form of any of the embodiments of the integrated circuit component 920 discussed above. The package-on-package structure 934 may be configured in accordance with any of the package-on-package structures known in the art.

FIG. 10 is a block diagram of an example electrical device 1000 that may include one or more of the embodiments disclosed herein. For example, any suitable ones of the components of the electrical device 1000 may include one or more of the integrated circuit device assemblies 900, integrated circuit components 920, integrated circuit devices 800, or integrated circuit dies 702 disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power circuitry 1014. The battery/power circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include an other output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include another input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is a transistor device comprising: a substrate; a first source or drain material on the substrate; a semiconductor material on the first source or drain material; a second source or drain material on the semiconductor material; a first dielectric material on the substrate and adjacent the first source or drain material; a ferroelectric (FE) material on the first dielectric material and adjacent the semiconductor material; a gate material on the on the first dielectric material and adjacent the FE material; and a second dielectric material on the FE material and gate material, the second dielectric material adjacent the second source or drain material.

Example 2 includes the subject matter of Example 1, wherein a lattice parameter of the semiconductor material is higher than a lattice parameter of the FE material.

Example 3 includes the subject matter of Example 1 or 2, wherein the FE material is a perovskite material.

Example 4 includes the subject matter of any one of Examples 1-3, wherein the FE material includes one or more of Barium, Titanium, Zirconium, Calcium, Strontium, Lanthanum, Bismuth, Iron, Cobalt, Lithium, Niobium, Potassium, and Oxygen.

Example 5 includes the subject matter of any one of Examples 1-4, wherein the semiconductor material includes one or more of Barium, Tin, Lanthanum, Neodymium, Strontium, Titanium, Indium, Gallium, Zinc, Nickel, and Oxygen.

Example 6 includes the subject matter of any one of Examples 1-5, wherein the substrate comprises one or more of Strontium, Titanium, Gadolinium, Scandium, Dysprosium, Lanthanum, Aluminum, Barium, Hafnium, Zirconium, Indium, Lutetium, Magnesium, and Oxygen.

Example 7 includes the subject matter of any one of Examples 1-6, wherein the first source or drain material and the second source or drain material each comprise one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

Example 8 includes the subject matter of any one of Examples 1-7, wherein the gate material comprises one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

Example 9 includes the subject matter of any one of Examples 1-8, wherein the FE material is a first FE material and the gate material is a first gate material, and the device further comprises: a third dielectric material on the substrate and adjacent the first source or drain material; a second FE material on the third dielectric material and adjacent the semiconductor material; a second gate material on the on the third dielectric material and adjacent the second FE material; a fourth dielectric material on the second FE material and the second gate material, the fourth dielectric material adjacent the second source or drain material.

Example 10 includes the subject matter of any one of Examples 1-9, wherein the semiconductor material is a first semiconductor material, and the device further comprises: a third dielectric material on the second source or drain material; a third second source or drain material on the dielectric; a second semiconductor material on the third source or drain material; a fourth source or drain material on the second semiconductor material; a second FE material on the second dielectric material and adjacent the second semiconductor material, wherein the gate material is further adjacent the second FE material; and a fourth dielectric material on the second FE material and the gate material.

Example 11 is a transistor device comprising: a substrate; a first source or drain material on the substrate; a semiconductor material on the first source or drain material; a second source or drain material on the semiconductor material; a dielectric layer on the substrate and adjacent the first source or drain material; a ferroelectric (FE) material on the dielectric layer and adjacent the semiconductor material, wherein the FE material has a lattice parameter that is less than a lattice parameter of the semiconductor material; and a gate material on or adjacent to the FE material.

Example 12 includes the subject matter of Example 11, wherein the FE material is a perovskite material.

Example 13 includes the subject matter of Example 11 or 12, wherein the FE material includes one or more of Barium, Titanium, Zirconium, Calcium, Strontium, Lanthanum, Bismuth, Iron, Cobalt, Lithium, Niobium, Potassium, and Oxygen.

Example 14 includes the subject matter of any one of Examples 11-13, wherein the semiconductor material includes one or more of Barium, Tin, Lanthanum, Neodymium, Strontium, Titanium, Indium, Gallium, Zinc, Nickel, and Oxygen.

Example 15 includes the subject matter of any one of Examples 11-14, wherein the substrate comprises one or more of Strontium, Titanium, Gadolinium, Scandium, Dysprosium, Lanthanum, Aluminum, Barium, Hafnium, Zirconium, Indium, Lutetium, Magnesium, and Oxygen.

Example 16 includes the subject matter of any one of Examples 11-15, wherein the first source or drain material and the second source or drain material each comprise one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

Example 17 includes the subject matter of any one of Examples 11-16, wherein the gate material comprises one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

Example 18 includes the subject matter of any one of Examples 11-17, wherein the FE material is a first FE material, the gate material is a first gate material, and the dielectric layer is a first dielectric layer, and the device further comprises: a second dielectric layer on the substrate and adjacent the first source or drain material; a second FE material on the second dielectric material and adjacent the semiconductor material; and a second gate material on the on the third dielectric material and adjacent the second FE material.

Example 19 includes the subject matter of any one of Examples 11-18, wherein the semiconductor material is a first semiconductor material, and the device further comprises: a second dielectric material on the second source or drain material; a third second source or drain material on the dielectric; a second semiconductor material on the third source or drain material; a fourth source or drain material on the second semiconductor material; a second FE material adjacent the second semiconductor material, wherein the gate material is further adjacent the second FE material; and a third dielectric material between the first FE material and the second FE material.

Example 20 is a method of manufacturing a transistor device comprising: forming a first source or drain material on a substrate; forming a semiconductor material on the first source or drain material; forming a second source or drain material on the semiconductor material; forming a dielectric layer on the substrate adjacent the first source or drain material; forming a ferroelectric (FE) material on the dielectric layer adjacent the semiconductor material, wherein the FE material has a lattice parameter that is less than a lattice parameter of the semiconductor material; and forming a gate material on or adjacent to the FE material.

Example 21 includes the subject matter of Example 20, wherein the FE material is a perovskite material.

Example 22 includes the subject matter of Example 20 or 21, wherein the FE material includes one or more of Barium, Titanium, Zirconium, Calcium, Strontium, Lanthanum, Bismuth, Iron, Cobalt, Lithium, Niobium, Potassium, and Oxygen.

Example 23 includes the subject matter of any one of Examples 20-22, wherein the semiconductor material includes one or more of Barium, Tin, Lanthanum, Neodymium, Strontium, Titanium, Indium, Gallium, Zinc, Nickel, and Oxygen.

Example 24 includes the subject matter of any one of Examples 20-23, wherein the FE material is a first FE material, the gate material is a first gate material, and the dielectric layer is a first dielectric layer, and the method further comprises: forming a second dielectric layer on the substrate and adjacent the first source or drain material; forming a second FE material on the second dielectric material and adjacent the semiconductor material; and forming a second gate material on the on the third dielectric material and adjacent the second FE material.

Example 25 includes the subject matter of any one of Examples 20-24, wherein the semiconductor material is a first semiconductor material, and the method further comprises: a forming a second dielectric material on the second source or drain material; forming a third second source or drain material on the second dielectric material; forming a second semiconductor material on the third source or drain material; forming a fourth source or drain material on the second semiconductor material; forming a second FE material adjacent the second semiconductor material, wherein the gate material is further adjacent the second FE material; and forming a third dielectric material between the first FE material and the second FE material.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. A transistor device comprising:
a substrate;
a first source or drain material on the substrate;
a semiconductor material on the first source or drain material;
a second source or drain material on the semiconductor material;
a first dielectric material on the substrate and adjacent the first source or drain material;
a ferroelectric (FE) material on the first dielectric material and adjacent the semiconductor material;
a gate material on the on the first dielectric material and adjacent the FE material; and
a second dielectric material on the FE material and gate material, the second dielectric material adjacent the second source or drain material.

2. The device of claim 1, wherein a lattice parameter of the semiconductor material is higher than a lattice parameter of the FE material.

3. The device of claim 1, wherein the FE material is a perovskite material.

4. The device of claim 1, wherein the FE material includes one or more of Barium, Titanium, Zirconium, Calcium, Strontium, Lanthanum, Bismuth, Iron, Cobalt, Lithium, Niobium, Potassium, and Oxygen.

5. The device of claim 1, wherein the semiconductor material includes one or more of Barium, Tin, Lanthanum, Neodymium, Strontium, Titanium, Indium, Gallium, Zinc, Nickel, and Oxygen.

6. The device of claim 1, wherein the substrate comprises one or more of Strontium, Titanium, Gadolinium, Scandium, Dysprosium, Lanthanum, Aluminum, Barium, Hafnium, Zirconium, Indium, Lutetium, Magnesium, and Oxygen.

7. The device of claim 1, wherein the first source or drain material and the second source or drain material each comprise one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

8. The device of claim 1, wherein the gate material comprises one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

9. The device of claim 1, wherein the FE material is a first FE material and the gate material is a first gate material, and the device further comprises:
a third dielectric material on the substrate and adjacent the first source or drain material;
a second FE material on the third dielectric material and adjacent the semiconductor material;
a second gate material on the on the third dielectric material and adjacent the second FE material;
a fourth dielectric material on the second FE material and the second gate material, the fourth dielectric material adjacent the second source or drain material.

10. The device of claim 1, wherein the semiconductor material is a first semiconductor material, and the device further comprises:
a third dielectric material on the second source or drain material;
a third source or drain material on the third dielectric material;
a second semiconductor material on the third source or drain material;
a fourth source or drain material on the second semiconductor material;
a second FE material on the second dielectric material and adjacent the second semiconductor material, wherein the gate material is further adjacent the second FE material; and
a fourth dielectric material on the second FE material and the gate material.

11. A transistor device comprising:
a substrate;
a first source or drain material on the substrate;
a semiconductor material on the first source or drain material;
a second source or drain material on the semiconductor material;
a dielectric layer on the substrate and adjacent the first source or drain material;
a ferroelectric (FE) material on the dielectric layer and adjacent the semiconductor material, wherein the FE material has a lattice parameter that is less than a lattice parameter of the semiconductor material; and
a gate material on or adjacent to the FE material.

12. The device of claim 11, wherein the FE material is a perovskite material.

13. The device of claim 11, wherein the FE material includes one or more of Barium, Titanium, Zirconium, Calcium, Strontium, Lanthanum, Bismuth, Iron, Cobalt, Lithium, Niobium, Potassium, and Oxygen.

14. The device of claim 11, wherein the semiconductor material includes one or more of Barium, Tin, Lanthanum, Neodymium, Strontium, Titanium, Indium, Gallium, Zinc, Nickel, and Oxygen.

15. The device of claim 11, wherein the substrate comprises one or more of Strontium, Titanium, Gadolinium, Scandium, Dysprosium, Lanthanum, Aluminum, Barium, Hafnium, Zirconium, Indium, Lutetium, Magnesium, and Oxygen.

16. The device of claim 11, wherein the first source or drain material and the second source or drain material each comprise one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

17. The device of claim 11, wherein the gate material comprises one or more of Strontium, Ruthenium, Barium, Lanthanum, Tin, Manganese, Cobalt, Nickel, Yttrium, Copper, Vanadium, Molybdenum, Platinum, Iridium, Palladium, Tungsten, and Oxygen.

18. The device of claim 11, wherein the FE material is a first FE material, the gate material is a first gate material, and the dielectric layer is a first dielectric layer, and the device further comprises:
a second dielectric layer on the substrate and adjacent the first source or drain material;
a second FE material on the second dielectric material and adjacent the semiconductor material; and
a second gate material on the on the third dielectric material and adjacent the second FE material.

19. The device of claim 11, wherein the semiconductor material is a first semiconductor material, and the device further comprises:
a second dielectric material on the second source or drain material;
a third source or drain material on the second dielectric material;
a second semiconductor material on the third source or drain material;
a fourth source or drain material on the second semiconductor material;
a second FE material adjacent the second semiconductor material, wherein the gate material is further adjacent the second FE material; and
a third dielectric material between the first FE material and the second FE material.

20. A method of manufacturing a transistor device comprising:
forming a first source or drain material on a substrate;
forming a semiconductor material on the first source or drain material;
forming a second source or drain material on the semiconductor material;
forming a dielectric layer on the substrate adjacent the first source or drain material;
forming a ferroelectric (FE) material on the dielectric layer adjacent the semiconductor material, wherein the FE material has a lattice parameter that is less than a lattice parameter of the semiconductor material; and
forming a gate material on or adjacent to the FE material.

21. The method of claim 20, wherein the FE material is a perovskite material.

22. The method of claim 20, wherein the FE material includes one or more of Barium, Titanium, Zirconium, Calcium, Strontium, Lanthanum, Bismuth, Iron, Cobalt, Lithium, Niobium, Potassium, and Oxygen.

23. The method of claim 20, wherein the semiconductor material includes one or more of Barium, Tin, Lanthanum, Neodymium, Strontium, Titanium, Indium, Gallium, Zinc, Nickel, and Oxygen.

24. The method of claim 20, wherein the FE material is a first FE material, the gate material is a first gate material, and the dielectric layer is a first dielectric layer, and the method further comprises:
forming a second dielectric layer on the substrate and adjacent the first source or drain material;
forming a second FE material on the second dielectric material and adjacent the semiconductor material; and
forming a second gate material on the on the third dielectric material and adjacent the second FE material.

25. The method of claim 20, wherein the semiconductor material is a first semiconductor material, and the method further comprises:
forming a second dielectric material on the second source or drain material;
forming a third source or drain material on the second dielectric material;
forming a second semiconductor material on the third source or drain material;
forming a fourth source or drain material on the second semiconductor material;
forming a second FE material adjacent the second semiconductor material, wherein the gate material is further adjacent the second FE material; and
forming a third dielectric material between the first FE material and the second FE material.
